(19) United States
(12) Patent Application Publication
(10) Pub. No.: US 2019/0364681 A1
(43) Pub. Date: Nov. 28, 2019

(54) PANEL DOOR FOR A NETWORK ENCLOSURE BOX

(71) Applicant: Sumitomo Electric Lightwave Corp., Raleigh, NC (US)

(72) Inventors: Daniel Brian Hangebrauck, Garner, NC (US); Daniel Frederick Oberklein, Cary, NC (US); Patrick S. VanVickle, Apex, NC (US)

(21) Appl. No.: 15/986,664

(22) Filed: May 22, 2018

(51) Int. Cl. H05K 5/02; H05K 7/18; H05K 7/14; E05C 1/00; E05C 1/02

(52) U.S. Cl. CPC H05K 5/0221; H05K 7/186; E05C 1/02; E05C 1/006; H05K 7/1411

(57) ABSTRACT

A rear panel door for an enclosure box (e.g., of a network or computing module) is attached to the enclosure module without the use of conventional hinges, instead using pins and hooks to hold the panel door onto the enclosure module. Lower hooks provide rotation for opening and closing the panel door, as well as for securing the panel door to the enclosure module while the panel door is in the open position. Upper hooks provide a latching feature to secure the panel door to the enclosure module when the panel door is in the closed position. The door can be opened directly from the rear side of the enclosure module (e.g., using integral finger holes or slots formed in the panel door and/or enclosure module) or by applying an interior pressure from within the enclosure module.

### TECHNICAL FIELD

The subject matter herein relates generally to network enclosures, systems, and/or methods. More particularly, the subject matter disclosed herein relates to rack-mounted network equipment.

### BACKGROUND

Communication networks are frequently built using a plurality of network racks that hold a number of network equipment modules, which are modular components used for a variety of communication tasks. A standard rack typically has several modules, or “shelves” which are sized according to a standardized rack unit (RU) equal to 1.75″ tall. A standard rack can hold up to several dozen network modules. These shelves often have a front, user-accessible side, and a rear side which is reserved for cooling, cable routing, intra-rack connections, etc. The rear side may be accessed primarily during installation, maintenance, and trouble-shooting. Therefore, although it may be necessary to occasionally access the rear side of a network shelf, it is not necessary to provide an elaborate user interface. Existing designs often use doors attached by various hinge mechanisms. Panel doors using such hinge mechanisms require at least several discrete parts, which add cost and complexity to the network shelf. Accordingly, there is a continued need to provide a simple, ergonomic way to access the rear side of the network shelf, minimizing the components, cost, and weight of such a network shelf.

### SUMMARY

Optical fiber network devices, systems, and related methods are provided herein to provide improved access to an interior of rack-mounted network equipment, such a network shelf, from the rear side thereof.

With a system as disclosed herein, an operator can quickly and easily access the interior of the network shelf from a rear side thereof, and the network shelf can have a minimum amount of material, parts, and complexity. Use of a panel door with tabs that provide both the pivoting and latching functions eliminates the need for additional hardware that is ubiquitous in solutions known from the prior art, such systems requiring only four small studs to be provided on the body of a network shelf. This system thus comprises a panel door design that is easy to operate and provides additional functionality not found in existing designs.

In some aspects, a panel door for a network enclosure box has a central region that is substantially planar and latching tab regions located symmetrically on opposite sides of the central region in a plane perpendicular to the central region. The latching tabs each have lower and upper hooks. The hooks are configured to provide rotating and latching functions.

### BRIEF DESCRIPTION OF THE DRAWINGS

A full and enabling disclosure of the present subject matter is set forth more particularly in the remainder of the specification, including reference to the accompanying figures, (also, “Figs.”) that are given merely by way of explanatory and non-limiting example, relating to one or more example embodiments, in which:

FIG. 1A is a front perspective assembly view of modules mounted in a rack frame, in accordance with the disclosure herein;

FIG. 1B is a rear perspective assembly view of modules installed in the rack frame of FIG. 1A, in accordance with the disclosure herein;

FIG. 2A is an isometric view of an example embodiment of a panel door, in accordance with the disclosure herein;

FIG. 2B is a side view of the example embodiment of the panel door of FIG. 2A, in accordance with the disclosure herein;

FIGS. 3-6 are perspective views of an example embodiment of a panel door in a plurality of installation positions on a module as shown in FIGS. 1A and 1B, in accordance with the disclosure herein; and

FIG. 7 is a perspective view of the example embodiment of the panel door of FIGS. 3-6, positioned for removal, in accordance with the disclosure herein.

### DETAILED DESCRIPTION

The present subject matter provides a rear panel door capable of improving ease of installation and maintenance of network equipment modules. In this way, the devices, systems, and methods disclosed herein can be used to reduce installation time and cost, as well as to reduce weight and complexity of network equipment modules. Another benefit of the panel door described herein is that it can be easily retrofitted to existing network equipment without significantly changing an existing design.

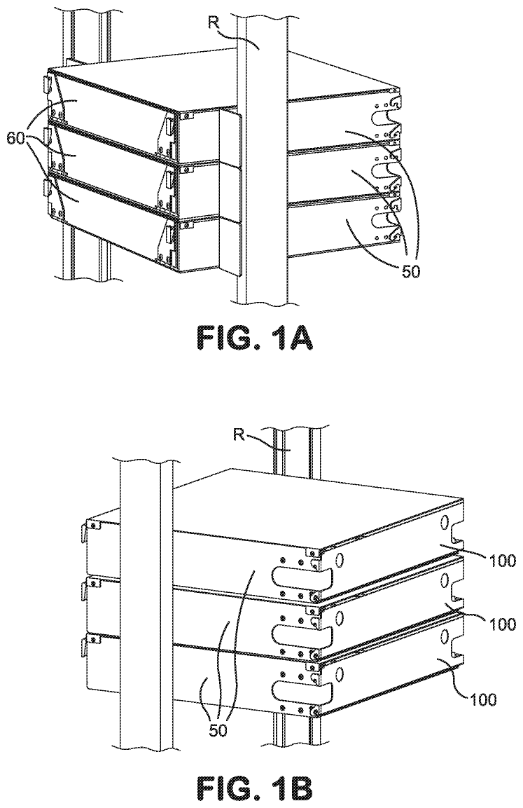

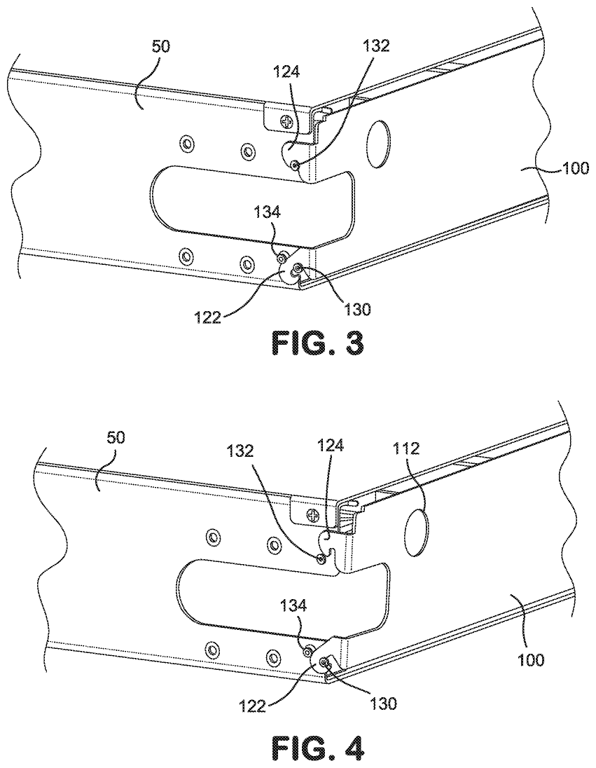

In one aspect, an example embodiment of a rack frame R, which can be a rack frame for an installation of networking or computing equipment, populated with modules 50 is shown in FIGS. 1A-1B. Modules 50 can be network communications modules or any other suitable enclosure for network equipment, such as a computing server. FIG. 1A depicts rack frame R from a front perspective view, showing modules 50 mounted to rack frame R with brackets B. In this example embodiment, modules 50 are each depicted as an enclosure with lateral side panels, top and bottom panels, and substantially open front and rear sides, except as blocked by respective front and rear cover panels 60 and 100, respectively. Modules 50 are illustrated as having a height of 2RU (2 rack units, with one rack unit being equal to 1.75 inches); however, other shelf heights can be envisioned, e.g., 1U, 3U, 4U, 5U, etc. FIG. 1B depicts rack frame R and modules 50 from a rear perspective view. In FIG. 1B, a rear panel door, generally designated 100, is shown covering the rear opening of module 50. Panel door 100 is configured to rotate outward, as will be described further herein with respect to FIGS. 3-7, to allow an operator or installer to access components inside module 50.

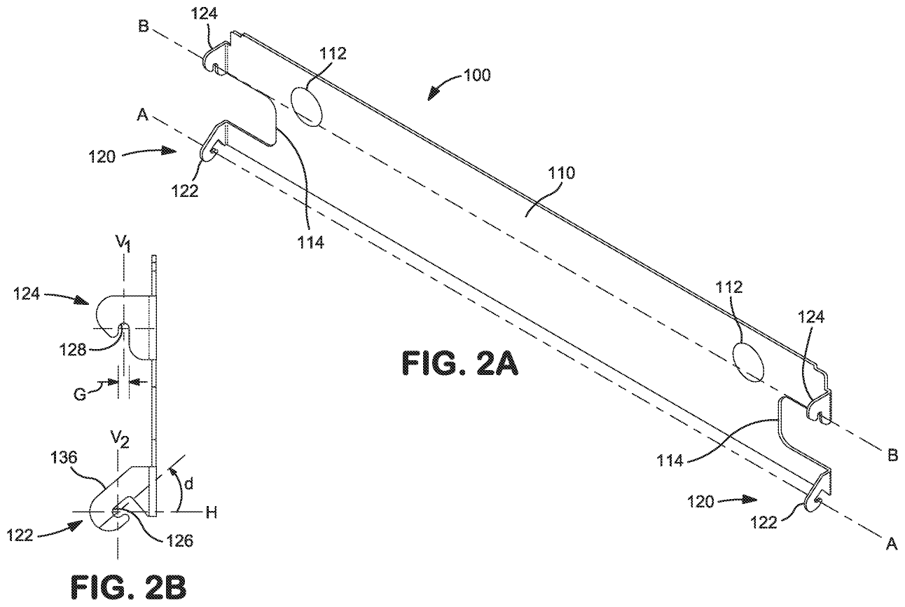

Referring to FIGS. 2A-2B, details of panel door 100 are shown. Panel door 100 has two main regions: a substantially planar central region 110 and two tab regions, generally designated 120, located on opposite ends of central region 110. Each tab region 120 comprises two “hook” features, lower hook 122 and upper hook 124. Lower and upper hooks 122, 124 serve the purpose of providing rotation and retention, respectively, for attaching panel door 100 to module 50. Lower hooks 122 are located at opposing ends of central region 110 and are symmetrically aligned such that the open regions thereof define an axis of rotation A-A. Likewise, upper hooks 124 are located at opposing ends of central region 110 vertically over the lower hooks 122 and are symmetrically aligned such that the open regions thereof define an axis B-B. In the example embodiment shown in FIG. 2A, panel door 100 is formed of a single piece of sheet metal and brake-formed to create tab regions 120. In some embodiments, panel door 100 can be made of other materials, (e.g., plastic), and can be formed in different ways, such as by injection molding. In the embodiment shown in FIG. 2A, panel door 100 includes finger holes 112 and cutouts 114 to assist an operator or user in opening and closing panel door 100, and which can also provide ventilation to the equipment housed within. In some embodiments, finger holes 112 and/or cutouts 114 can be omitted.

It can be seen in FIG. 2B that lower hooks 122 and upper hooks 124 are configured such that the open regions of the hooks are disposed at different angles relative to each other. For example, in an embodiment with panel door 100 having a vertical orientation when installed in a closed position on an enclosure of a module (e.g., 50, FIG. 1B), upper hooks 124 have mating portion 128, which opens downwardly in a direction of gravity along a vertical axis V₁. Lower hooks 122 have mating portion 126, which opens at a diagonal angle d between horizontal axis H and a second vertical axis V₂. Axes V₁ and V₂ are illustrates as being aligned to be coplanar with each other but can, in some embodiments, be disposed in planes offset from one another (e.g., in the direction of horizontal axis H). As used herein, the term “open region” refers to the region of the hooks which can also be described as a “gap”, or the shortest (e.g., approximately perpendicular) distance between the terminal end of the hook and the opposing body portion of the hook. For example, the gap distance of upper hook 124 in FIG. 2B is represented by dimension G. The “angle” of the hook is defined as a direction substantially perpendicular to this distance.

In some embodiments, lower hooks 122 can also be configured to use an outer surface of the hook 136 as a guiding surface for insertion and removal. For example, outer surface 136 can engage with a guide pin on the lateral side panels of module 50 to assist in prescribing the movement path of panel door 100 (see, e.g., guide pin 134, FIGS. 3-5).

Referring to FIGS. 3-5, details of the rotation and retention functions of panel door 100 are illustrated. FIG. 3 depicts panel door 100 in a fully closed position on module 50. Module 50 is equipped with retention features, such as protruding studs or pins, shown in the example embodiment of FIGS. 3-5, where module 50 has lower pins 130 and upper pins 132 disposed on the lateral sides of module 50 in a position that corresponds to the positions of the lower hooks 122 and the upper hooks 124 on panel door 100, respectively, and allows for engagement of the lower and upper hooks 122 and 124 with the respective lower and upper pins 130 and 132. When module 50 is closed, lower hooks 122 are engaged over lower pins 130, and each upper hook 124 of panel door 100 is configured to engage with a corresponding upper pin 132, such that each upper pin 132 is held within gap G formed by the respective portions of a corresponding upper hook 124. In this position the diagonal or ramped angle of lower hooks 122 causes the lower portion of panel door 100 to be drawn in to rest snugly against the body of network module 50 as panel door 100 hangs under its own weight. Lower hooks 124 are thus engaged in a resting position along a linear region of mating portion 126. Each lower pin 130 is not fully engaged with lower hook, but is held in place by the inclined portion of lower hook due to angle d noted in the description of FIG. 2B.

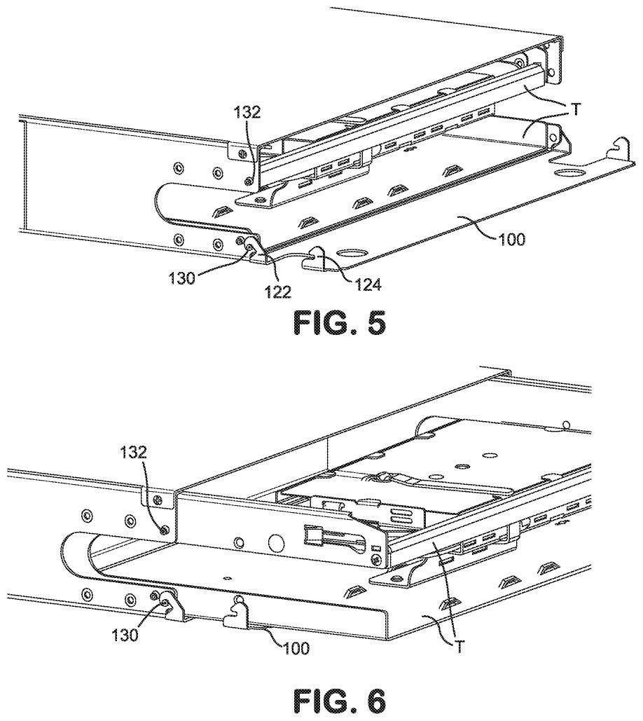

FIG. 4 shows panel door 100 in mid-position as it is opened or closed. Opening is initiated by pulling panel door 100 in a vertically upward direction (e.g., with a force substantially aligned with a height of door panel 100). This can be accomplished, for example, by manually using finger holes 112 to disengage upper hooks 124. As panel door 100 moves vertically upwards, upper hooks 124 slide up by a distance corresponding to a vertical distance moved by door panel 100, such that upper pins 132 are no longer held captive within the gap formed by the respective portions of the respective upper hooks 124. Once the upper hooks 124 are no longer positively engaged with the uppers pins 130, the panel door 100 is then free to rotate outwardly from module 50 around an axis defined by lower pins 130. During this upward movement of door panel 100 to disengage upper hooks 124 from upper pins 132, lower hooks 122 travel along the diagonal angle (see, e.g., d, FIG. 2B) so that lower pins 130 are fully engaged within the gap formed by the respective portions of lower hooks 122. This full engagement of lower pins 130 within the gaps of the lower hooks 122 allows the lower hooks to hold the bottom edge of panel door 100 in place (e.g., cannot move farther away from the rear of module 50). With lower hooks 122 fully engaged against lower pins 130, panel door 100 can rotate outward from module 50 toward a horizontal orientation, shown in FIG. 5.

To close panel door 100, the steps described above can be performed in reverse. Lower hooks 122 are first engaged, or “hooked” over lower pins 130. This captures panel door 100 onto a lower edge of module 50. Panel door 100 is then rotated toward upper pins 132. The operator can grip finger holes 112, cutouts 114, or simply the sides of tab regions 120 to lift panel door 100 over upper pins 132. The door is prevented from separating from module 50 due to the angled opening of lower hook 122 as described above. Once the gap G is positioned over upper pins 132, panel door 100 can be released to drop onto pins 130, and panel door 100 will slide downward and against module 50.

FIGS. 3 and 4 additionally illustrate an additional guide pin 134 located on network module 50. Lower hooks 122 can be configured to mate with guide pin 134 using outer surface 136 of lower hook 122 in order to provide additional guidance for operating panel door 100. Guide pin 134 additionally prevents unintentional door detachment during opening and closing. Guide pin 134 can be located on one or both lateral sides of network enclosure 50. In some embodiments guide pin 134 can be omitted.

Another advantageous feature of panel door 100 is that the door can be opened from a direction inside module 50. The curvature of lower hook 122 is shaped in such a way that, when rearward pressure is applied to central region 110 from the interior of module 50, mating portion 126 of lower hooks 122 causes the door to move vertically upward and disengage upper hooks 124 from upper pins 132. Panel door 100 can then fall open to a horizontal position as lower hooks 122 rotate around the axis of rotation defined by lower pins 130. Thus, panel door 100 can be opened by, for example, using a sliding drawer or tray (e.g., label, FIGS. 5 and 6) located in module 50 to “bump” against and door panel 100. This “bump” feature allows the panel door 100 to be opened from the front of module 50, without the need for the operator to be physically present behind the rack frame (see, e.g., R FIGS. 1A and 1B).

FIG. 5 shows panel door 100 in a fully open, horizontal position. In the open position, panel door 100 is coplanar with a bottom panel of module 50. A lower edge of panel door 100 is pressed against a lower rear edge of the bottom panel of module 50, holding the panel door 100 in the horizontal (e.g., open) position, while lower hooks 122 remain engaged with the respective bottom pins 130, preventing door panel 100 from being separated from module 50 without further manipulation of door panel 100. When door panel 100 is in the open position, the contents of module 50 are accessible to an operator or user and can be, for example, removed from module 50.

Referring to FIG. 6, the horizontal, coplanar position of panel door 100 with module 50 allows an operator to access the interior of module 50. As depicted in FIG. 6, the operator can, for example, pull out a sliding tray T from module 50. In some embodiments, panel door 100 is configured to provide additional vertical support for a sliding tray T as it is removed from module 50. Depending on the dimensions of panel door 100, the support surface provided is sufficiently large to serve as a work surface whereby the components installed on sliding tray T may be reworked, replaced, or otherwise manipulated.

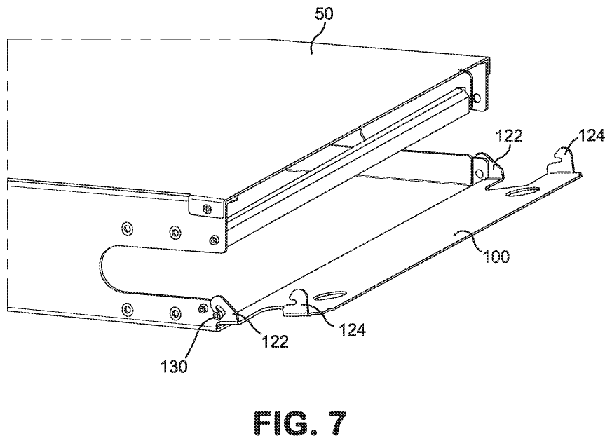

In some embodiments, panel door 100 can be removed entirely from module 50. FIG. 7 depicts panel door 100 in a position for removal from module 50. Panel door 100 is removed by first positioning it in a horizontal (fully open) orientation. The operator lifts panel door 100 vertically upwards (e.g., in the direction of the plane of panel door in the closed position, see FIG. 3) and pulls panel door 100 away from module 50, thus disengaging lower hooks 122 from lower pins 130. In some embodiments, it may be necessary to partially rotate panel door 100 towards the closed position while the upward force is applied so that the lower hoods 122 can be disengaged from the lower pins 130, depending on the length of the engagement channel of lower hooks 122 to engage with lower pins 130 when panel door 100 is in the closed position. This feature requiring substantially simultaneous rotation and vertical displacement can be advantageous in preventing unintended disengagements of door panel 100 from module 50 due to unintended vertical displacements or rotational movements of door panel 100 caused by an inattentive operator at the rear of module 50 or, in embodiments where panel door 100 can be opened by “bumping” from inside module 50, from vibrations or rotational “kickbacks” produced when panel door 100 impacts module 50 when freely falling into the open position. By carefully shaping lower hooks 122 to have the correct length and gap angle (e.g., d, FIG. 2B), panel door 100 is readily removable from module 50, yet is unlikely to be accidentally removed in the normal course of motion that occurs during the process of opening and closing panel door 100. The installation of panel door 100 onto module 50 is accomplished by simply performing the above-described process in reverse: lower hooks 122 are hooked over lower pins 130 and panel door 100 is rotated vertically upward to be captured against module 50.

While the subject matter has been described herein with reference to specific aspects, features, and illustrative embodiments, it will be appreciated that the utility of the subject matter is not thus limited, but rather extends to and encompasses numerous other variations, modifications and alternative embodiments, as will suggest themselves to those of ordinary skill in the field of the present subject matter, based on the disclosure herein.

Various combinations and sub-combinations of the structures and features described herein are contemplated and will be apparent to a skilled person having knowledge of this disclosure. Any of the various features and elements as disclosed herein can be combined with one or more other disclosed features and elements unless indicated to the contrary herein. Correspondingly, the subject matter as hereinafter claimed is intended to be broadly construed and interpreted, as including all such variations, modifications and alternative embodiments, within its scope and including equivalents of the claimed elements.

What is claimed is:

1. A panel door for an enclosure module, comprising:
a central portion; and
two latching tab portions disposed on opposite sides of the central portion, wherein each of the two latching tab portions are arranged, respectively, in a plane that is substantially perpendicular to a direction of extension of the central portion, and wherein each of the latching tab portions have a lower hook and an upper hook,
wherein each lower hook is configured to engage with a lower pin mounted on a lateral side panel of the enclosure module,
wherein each lower hook is configured to rotate, respectively, about the lower pin as the panel door moves between open and closed positions,
wherein each upper hook is configured to mate with an upper pin mounted on the lateral side panel of the enclosure module, and
wherein each upper hook is configured to hold the panel door in the closed position.

2. The panel door of claim 1, wherein the panel door is configured such that, when in the open position, the panel door rests in a substantially horizontal plane.

3. The panel door of claim 2, wherein the panel door remains in the substantially horizontal plane by engagement of at least part of an edge of the central portion against an edge of a bottom panel of the enclosure module.

4. The panel door of claim 1, further comprising finger holes in the central portion.

5. The panel door of claim 1, wherein the mating portion of the lower hook is configured to open at an angle in the range of 35-55 degrees above horizontal.

6. The panel door of claim 1, wherein the panel door is further configured to be opened by pushing on the central region from a direction inside the enclosure module and causing the upper hooks to lift off of the upper pins.

7. The panel door of claim 1, wherein the lower hooks are configured to engage with additional guide pins mounted on the lateral side panels of the enclosure module using an outer edge of the lower hooks to maintain the mechanical coupling between the panel door and the enclosure module.

8. The panel door of claim 1, wherein, when the panel door is in the closed position, a mating portion of the lower hook is configured to open at an angle above a horizontal plane, and a mating portion of the upper hook is configured to open downward at a vertical angle.

9. A network module for a communications network, comprising:
a panel door, the panel door comprising:
a central portion; and
two latching tab portions disposed on opposite sides of the central portion, wherein each of the two latching tab portions are arranged, respectively, in a plane that is substantially perpendicular to a direction of extension of the central portion, and wherein each of the latching tab portions have a lower hook and an upper hook,
wherein each lower hook is configured to engage with a lower pin mounted on a lateral side panel of the enclosure module,
wherein each lower hook is configured to rotate, respectively, about the lower pin as the panel door moves between open and closed positions,
wherein each upper hook is configured to mate with an upper pin mounted on the lateral side panel of the enclosure module,
wherein each upper hook is configured to hold the panel door in the closed position, and
wherein, when the panel door is in the closed position, a mating portion of the lower hook is configured to open at an angle above a horizontal plane, and a mating portion of the upper hook is configured to open downward at a vertical angle.

10. A method of manually moving a panel door from the closed position to the open position, comprising:
pulling the panel door in a vertically upward direction until the upper pins are no longer engaged with the upper hooks;
rotating the panel door outwardly from the module around an axis defined by the lower pins until lower pins are fully engaged with the lower hooks; and
rotating the panel door to a horizontal orientation.

11. A method of manually moving a panel door of an enclosure module from the closed position to the open position, the panel door comprising:
a central portion; and
two latching tab portions disposed on opposite sides of the central portion, each of the latching tab portions having a lower hook and an upper hook,
wherein each lower hook is configured to engage with a lower pin mounted on a lateral side panel of the enclosure module,
wherein each lower hook is configured to rotate, respectively, about the lower pin as the panel door moves between open and closed positions,
wherein each upper hook is configured to mate with an upper pin mounted on the lateral side panel of the enclosure module, and
wherein each upper hook is configured to hold the panel door in the closed position;
the method comprising:
applying an outward pressure to the central portion from an interior of the enclosure module, causing the panel door to move in a vertically upward direction until the upper pins are no longer engaged with the upper hooks; and
allowing the panel door to fall open to a horizontal position as the lower hooks rotate around the axis of rotation defined by lower pins.

12. The method of claim 11, wherein applying an outward pressure comprises pressing a sliding drawer or tray against the panel door.
